(19) United States
(12) Patent Application Publication
(10) Pub. No.: US 2023/0168319 A1
(43) Pub. Date: Jun. 1, 2023

(54) IN-PLANE MAGNETIZED FILM MULTILAYER STRUCTURE, HARD BIAS LAYER, AND MAGNETORESISTIVE EFFECT ELEMENT

(71) Applicant: TANAKA KIKINZOKU KOGYO K.K., Tokyo (JP)

(72) Inventors: Ryousuke KUSHIBIKI, Tsukuba-shi (JP); Kim Kong THAM, Tsukuba-shi (JP); Tomonari KAMADA, Tsukuba-shi (JP)

(73) Assignee: TANAKA KIKINZOKU KOGYO K.K., Tokyo (JP)

(21) Appl. No.: 17/921,005

(22) PCT Filed: Apr. 28, 2021
(86) PCT No.: PCT/JP2021/016940

§ 371 Date: Oct. 24, 2022

(30) Foreign Application Priority Data
May 1, 2020 (JP) 2020-081598

(51) Int. Cl. G01R 33/09; H10N 50/10; H10N 50/85; H01F 10/16

(52) U.S. Cl. CPC G01R 33/093; H10N 50/10; H10N 50/85; H01F 10/16

(57) ABSTRACT

An in-plane magnetized film multilayer structure for use as a hard bias layer of a magnetoresistive effect element contains a plurality of in-plane magnetized films and a nonmagnetic intermediate layer. The nonmagnetic intermediate layer is disposed between the in-plane magnetized films, and the in-plane magnetized films adjacent across the nonmagnetic intermediate layer are coupled by a ferromagnetic coupling. Each of the in-plane magnetized films contains metal Co and metal Pt, and contains the metal Co in an amount of 45 at % or more and 80 at % or less and the metal Pt in an amount of 20 at % or more and 55 at % or less relative to a total of metal components of the each of the in-plane magnetized films. A total thickness of the plurality of in-plane magnetized films is 30 nm or more.

### TECHNICAL FIELD

The present invention relates to an in-plane magnetized film multilayer structure, a hard bias layer, and a magnetoresistive effect element, and more particularly relates to a CoPt-based in-plane magnetized film multilayer structure that can achieve magnetic performance of a magnetic coercive force Hc of 2.00 kOe or more and remanent magnetization per unit area Mrt of 2.00 memu/cm² or more without adopting film formation on a heated substrate (hereinafter also referred to as film formation with heating), a hard bias layer having the in-plane magnetized film multilayer structure, and a magnetoresistive effect element having the hard bias layer. The CoPt-based in-plane magnetized film multilayer structure can be used for the hard bias layer of a magnetoresistive effect element.

It is conceivable that a hard bias layer having a magnetic coercive force Hc of 2.00 kOe or more and remanent magnetization per unit area Mrt of 2.00 memu/cm² or more has as much or more magnetic coercive force and remanent magnetization than a hard bias layer of an existing magnetoresistive effect element.

In the present application, the hard bias layer refers to a thin-film magnet that applies a bias magnetic field to a magnetic layer exhibiting a magnetoresistive effect (hereinafter also referred to as a free magnetic layer).

In the present application, metal Co may be simply described as Co, metal Pt may be simply described as Pt, and metal Ru may be simply described as Ru. Other metal elements may be described as in the same manner.

In the present application, boron (B) is included in the category of a metal element.

### BACKGROUND ART

Currently, magnetic sensors are used in many fields, and one of the magnetic sensors used commonly is a magnetoresistive effect element.

A magnetoresistive effect element has a magnetic layer exhibiting a magnetoresistive effect (free magnetic layer) and a hard bias layer applying a bias magnetic field to the magnetic layer (free magnetic layer), and the hard bias layer is required to be able to apply a magnetic field of a predetermined strength or more to the free magnetic layer in a stable manner.

Thus, the hard bias layer is required to have a high magnetic coercive force and high remanent magnetization.

However, hard bias layers of existing magnetoresistive effect elements have a magnetic coercive force of about 2 kOe (for example, FIG. 7 of Patent Literature 1), and so an increase in the magnetic coercive force is desired.

The hard bias layer is also required to have remanent magnetization per unit area of about 2 memu/cm² or more (for example, paragraph 0007 of Patent Literature 2).

There is a technique described in Patent Literature 3 to accommodate thereto. In the technique described in Patent Literature 3, a seed layer (a composite seed layer including a Ta layer and a metal layer, which is formed on the Ta layer and has a face-centered cubic (111) crystal structure or a hexagonal closest packed (001) crystal structure) is provided between a sensor laminate (a laminate having a free magnetic layer) and a hard bias layer so as to orient a magnetic material such that an easy axis is oriented along a longitudinal direction, for the purpose of increasing the magnetic coercive force of the hard bias layer. However, the above-described magnetic characteristics required of the hard bias layer are not satisfied. In this technique, the seed layer provided between the sensor laminate and the hard bias layer needs to be thick in order to increase the magnetic coercive force. Therefore, the structure also has the problem of weakening a magnetic field to be applied to the free magnetic layer in the sensor laminate.

Patent Literature 4 describes use of FePt as a magnetic material to be used in a hard bias layer, the FePt hard bias layer having a Pt or Fe seed layer, and a Pt or Fe capping layer. Patent Literature 4 suggests a structure in which Pt or Fe contained in the seed layer and the capping layer and FePt contained in the hard bias layer are mixed with each other during annealing at an annealing temperature of approximately 250 to 350° C. However, in a heating process required for formation of the hard bias layer, it is necessary to consider effects on other films that have already been stacked. Thus, the heating process is a process to avoid as much as possible.

Patent Literature 5 describes that an annealing temperature can be lowered to about 200° C. by optimization of the annealing temperature. Patent Literature 5 describes that the magnetic coercive force of a hard bias layer is 3.5 kOe or more, but the remanent magnetization per unit area thereof is about 1.2 memu/cm², which does not satisfy the above-described magnetic characteristics required of the hard bias layer.

Patent Literature 6 describes a magnetic recording medium for longitudinal recording, the magnetic layers of which have a granular structure constituted of ferromagnetic crystal grains in a hexagonal closest packed structure and a nonmagnetic grain boundary, which surrounds the ferromagnetic crystal grains and is mainly made of an oxide. There have been no examples of such a granular structure used in a hard bias layer of a magnetoresistive effect element. The technique described in Patent Literature 6 aims at reduction in a signal-to-noise ratio, which is an object of a magnetic recording medium. The magnetic layers are stacked in layers by interposing a nonmagnetic layer between the magnetic layers. The upper and lower magnetic layers are coupled by an antiferromagnetic coupling, and hence have a structure unsuitable for increasing the magnetic coercive force of the magnetic layers.

In non-patent literature 1 and 2, efforts have been made to improve the recording and reproducing characteristics of magnetic recording media for longitudinal recording. Specifically, they describe the magnetic coercive force Hc of a CoPt alloy film with a thickness of 15 nm formed on a Ru substrate film deposited under high Ar gas pressure (6 Pa), and state that a magnetic coercive force in the longitudinal or in-plane direction indicates 8 kOe in a CoPt alloy film with a Pt content of 30 to 40 at %. However, remanent magnetization is not described, and it is unclear whether it meets the requirement of remanent magnetization per unit area (2.00 memu/cm² or more), which is desired as a hard bias layer for magnetoresistive effect elements. Therefore, the inventor conducted experiments for confirmation under similar conditions and found that the CoPt alloy film with a thickness of 15 nm described in non-patent literature 1 and 2 had remanent magnetization per unit area of less than 2.00 memu/cm², as shown in comparative examples 20 to 29, which will be explained later.

### CITATION LIST

### Patent Literature

Patent Literature 1: JP2008-283016

Patent Literature 2: JP2008-547150

Patent Literature 3: JP2011-008907

Patent Literature 4: US2009/0274931A1

Patent Literature 5: JP2012-216275

Patent Literature 6: JP2003-178423

### Non-Patent Literature

Non-Patent Literature 1: Journal of the Magnetics Society of Japan, Vol. 25, No. 4-2, p. 607-610, 2001

Non-Patent Literature 2: Journal of the Magnetics Society of Japan, Vol. 26, No. 4, pp. 269-273, 2002

### SUMMARY OF INVENTION

### Technical Problem

When the application to an actual magnetoresistive effect element is considered, a sensor laminate (a laminate having a free magnetic layer) and a hard bias layer are preferably made as thin as possible. Also, no film formation with heating is preferably performed.

In order to obtain a hard bias layer having a higher magnetic coercive force than that (about 2 kOe) of hard bias layers of existing magnetoresistive effect elements and higher remanent magnetization per unit area than that (about 2 memu/cm²) of the hard bias layers of the existing magnetoresistive effect elements, with the foregoing conditions satisfied, the inventors considered that it was necessary to search for different elements or compounds from elements or compounds used in the existing hard bias layers. The inventors also considered that it may be necessary to devise the layer composition of the hard bias layer. Specifically, the inventors considered that it would be promising to multilayer a CoPt-based in-plane magnetized film by a nonmagnetic intermediate layer.

In consideration of the aforementioned circumstances, an object of the present invention is to provide an in-plane magnetized film multilayer structure that can achieve magnetic performance of a magnetic coercive force Hc of 2.00 kOe or more and remanent magnetization per unit area Mrt of 2.00 memu/cm² or more, without adopting film formation with heating. A supplemental object of the present invention is to provide a hard bias layer having the in-plane magnetized film multilayer structure and a magnetoresistive effect element having the hard bias layer.

### Solution to Problem

The present invention has solved the above-described problems by the following in-plane magnetized film multilayer structure, hard bias layer, and magnetoresistive effect element.

That is, a first aspect of an in-plane magnetized film multilayer structure according to the present invention is an in-plane magnetized film multilayer structure for use as a hard bias layer of a magnetoresistive effect element, and is characterized in the following points. The in-plane magnetized film multilayer structure has a plurality of in-plane magnetized films and a nonmagnetic intermediate layer, and the nonmagnetic intermediate layer is disposed between the in-plane magnetized films, and the in-plane magnetized films adjacent across the nonmagnetic intermediate layer are coupled by a ferromagnetic coupling. Each of the in-plane magnetized films contains metal Co and metal Pt, and contains the metal Co in an amount of 45 at % or more and 80 at % or less and the metal Pt in an amount of 20 at % or more and 55 at % or less relative to a total of metal components of the each of the in-plane magnetized films. A total thickness of the plurality of in-plane magnetized films is 30 nm or more.

A second aspect of an in-plane magnetized film multilayer structure according to the present invention is an in-plane magnetized film multilayer structure for use as a hard bias layer of a magnetoresistive effect element, and is characterized in the following points. The in-plane magnetized film multilayer structure has a plurality of in-plane magnetized films and a nonmagnetic intermediate layer, and the nonmagnetic intermediate layer is disposed between the in-plane magnetized films, and the in-plane magnetized films adjacent across the nonmagnetic intermediate layer are coupled by a ferromagnetic coupling. Each of the in-plane magnetized films contains metal Co and metal Pt, and contains the metal Co in an amount of 45 at % or more and 80 at % or less and the metal Pt in an amount of 20 at % or more and 55 at % or less relative to a total of metal components of the each of the in-plane magnetized films. The in-plane magnetized film multilayer structure has a magnetic coercive force of 2.00 kOe or more and remanent magnetization per unit area of 2.00 memu/cm² or more.

In the present application, the hard bias layer refers to a thin-film magnet that applies a bias magnetic field to a free magnetic layer exhibiting a magnetoresistive effect.

In the present application, the nonmagnetic intermediate layer refers to a nonmagnetic layer disposed between the in-plane magnetized films.

In the present application, the ferromagnetic coupling refers to a coupling based on an exchange interaction produced when spins of magnetic layers (here, the in-plane magnetized films) that are adjacent across the nonmagnetic intermediate layer are in parallel (directed in the same direction).

In the present application, “remanent magnetization per unit area” of the in-plane magnetized film refers to the value obtained by multiplying remanent magnetization per unit volume of the in-plane magnetized film by the thickness of the in-plane magnetized film, and “remanent magnetization per unit area” of the in-plane magnetized film multilayer structure refers to the value obtained by multiplying remanent magnetization per unit volume of the in-plane magnetized films included in the in-plane magnetized film multilayer structure by the total thickness of the in-plane magnetized films included in the in-plane magnetized film multilayer structure.

Each of the in-plane magnetized films may contain boron in an amount of 0.5 at % or more and 3.5 at % or less relative to a total of metal components of the each of the in-plane magnetized films.

A thickness of the nonmagnetic intermediate layer is typically 0.3 nm or more and 3 nm or less.

The nonmagnetic intermediate layer is preferably made of Ru or a Ru alloy.

A thickness per one layer of the in-plane magnetized films is typically 5 nm or more and 30 nm or less.

A hard bias layer according to the present invention is a hard bias layer characterized by having the in-plane magnetized film multilayer structure.

A magnetoresistive effect element according to the present invention is a magnetoresistive effect element characterized by having the hard bias layer.

### Advantageous Effects of Invention

According to the present invention, it is possible to provide an in-plane magnetized film multilayer structure that can achieve magnetic performance of a magnetic coercive force Hc of 2.00 kOe or more and remanent magnetization per unit area Mrt of 2.00 memu/cm² or more, without adopting film formation with heating, a hard bias layer having the in-plane magnetized film multilayer structure, and a magnetoresistive effect element having the hard bias layer.

### BRIEF DESCRIPTION OF DRAWINGS

FIG. 1 is a cross-sectional view schematically showing a state in which an in-plane magnetized film multilayer structure 10 according to an embodiment of the present invention is applied to a hard bias layer 22 of a magnetoresistive effect element 20.

FIG. 2 is a diagrammatic perspective view schematically showing the form of a thinned sample 80 after being subjected to thinning processing.

FIG. 3 is an example of an observation image (an observation image of Example 10) obtained by imaging with a scanning transmission electron microscope.

FIG. 4 is a result of line analysis (elemental analysis) performed in a thickness direction of an in-plane magnetized film of the Example 10 (performed along a black line in FIG. 3).

### DESCRIPTION OF EMBODIMENTS

### (1) Outline of Embodiment According to the Present Invention

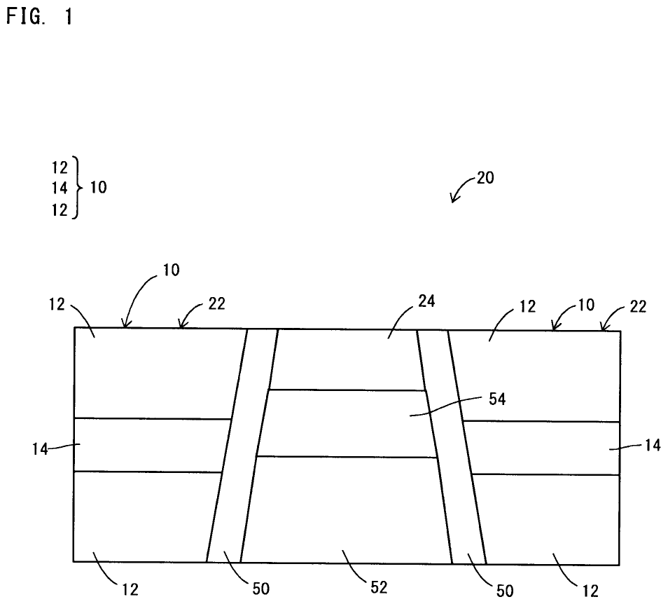

FIG. 1 is a cross-sectional view schematically showing a state in which an in-plane magnetized film multilayer structure 10 according to an embodiment of the present invention is applied to a hard bias layer 22 of a magnetoresistive effect element 20. In FIG. 1, a substrate layer (the in-plane magnetized film multilayer structure 10 is formed on the substrate layer) is omitted.

An explanation of the structure shown in FIG. 1 is as follows, with a tunneling magnetoresistive effect element as a magnetoresistive effect element 20 in mind. Note that the in-plane magnetized film multilayer structure 10 according to the present embodiment is not limited to application to a hard bias layer of the tunneling magnetoresistive effect element and is capable of being applied to, for example, a hard bias layer of a giant magnetoresistive effect element or an anisotropic magnetoresistive effect element.

The magnetoresistive effect element 20 (here, the tunneling magnetoresistive effect element) has two ferromagnetic layers (a free magnetic layer 24 and a pinned layer 52) separated by an extremely thin nonmagnetic tunnel barrier layer (hereinafter, a barrier layer 54). The direction of magnetization of the pinned layer 52 is fixed by securing the pinned layer 52 on an adjoining antiferromagnetic layer (not shown) by an exchange coupling, or the like. The direction of magnetization of the free magnetic layer 24 can freely rotate with respect to the direction of magnetization of the pinned layer 52, under the presence of an external magnetic field. Because the rotation of the free magnetic layer 24 with respect to the direction of magnetization of the pinned layer 52 by the external magnetic field causes a change in electric resistance, the detection of the change in the electric resistance allows for the detection of the external magnetic field.

The hard bias layer 22 plays a role in stabilizing a magnetization direction axis of the free magnetic layer 24 by applying a bias magnetic field to the free magnetic layer 24. An insulating layer 50 made of an electrically insulating material plays a role in preventing diversion of a sensor current that flows through a sensor laminate (the free magnetic layer 24, the barrier layer 54, and the pinned layer 52) in a vertical direction into the hard bias layer 22 on both sides of the sensor laminate (the free magnetic layer 24, the barrier layer 54, and the pinned layer 52).

### (2) In-Plane Magnetized Film Multilayer Structure

As shown in FIG. 1, the in-plane magnetized film multilayer structure 10 according to the embodiment of the present invention has a plurality of in-plane magnetized films 12, and further has a nonmagnetic intermediate layer 14 between the plurality of the in-plane magnetized films 12. Thus, the structure 10 has a stacked structure in which the plurality of in-plane magnetized films 12 are stacked via the non-magnetic intermediate layer 14. Thein-plane magnetized film multilayer structure 10 has as much or more magnetic coercive force (a magnetic coercive force of 2.00 kOe or more) and remanent magnetization per unit area (2.00 memu/cm² or more) as compared with those of the hard bias layers of existing magnetoresistive effect elements. The in-plane magnetized film multilayer structure 10 according to the present embodiment is able to be used as the hard bias layer 22 of the magnetoresistive effect element 20 and to apply the bias magnetic field to the free magnetic layer 24, which exhibits a magnetoresistive effect.

Each of the in-plane magnetized films 12 of the in-plane magnetized film multilayer structure 10 according to the present embodiment applies the bias magnetic field to the free magnetic layer 24, which exhibits a magnetoresistive effect. The in-plane magnetized film 12 is CoPt-based in-plane magnetized film, and contains metal Co and metal Pt. The in-plane magnetized film 12 contains the metal Co in an amount of 45 at % or more and 80 at % or less and the metal Pt in an amount of 20 at % or more and 55 at % or less relative to a total of metal components of the in-plane magnetized film.

In the in-plane magnetized film multilayer structure 10, the thickness per one layer of the in-plane magnetized films 12 is typically 5 nm or more and 30 nm or less. The total thickness (total of thicknesses) of the in-plane magnetized film 12 is preferably set to 30 nm or more from the viewpoint of adjusting the remanent magnetization Mrt to be 2 meum/cm² or more. Further, with respect to the upper limit of the total thickness (total of thicknesses) of the in-plane magnetized film 12, as will be described later, the adjacent in-plane magnetized films 12 separated by the interposition of the nonmagnetic intermediate layer 14 are coupled via a ferromagnetic coupling, and so, even if the total thickness (total of thicknesses) of the in-plane magnetized film 12 increases, the magnetic coercive force Hc does not decrease in theory, and thus there is no upper limit. Actually, it is confirmed by examples described later that the magnetic coercive force Hc is kept at 2.00 kOe or more at least when the total thickness (total of thicknesses) is up to 90 nm. In addition, the thickness per one layer of the in-plane magnetized films 12 in the in-plane magnetized film multilayer structure 10 is preferably 5 nm or more and 15 nm or less, and more preferably 10 nm or more and 15 nm or less, from the viewpoint of increasing the magnetic coercive force Hc more.

### (3) In-Plane Magnetized Film

As described above in “(2) In-plane magnetized film multilayer structure”, the in-plane magnetized film 12 of in-plane magnetized film multilayer structure according to the present embodiment contains Co and Pt as metal components, and the thickness per one layer of the in-plane magnetized films 12 is typically 5 nm or more and 30 nm or less.

The metal Co and the metal Pt become components of magnetic crystal grains (minute magnets) in the in-plane magnetized film 12 to be formed by sputtering.

Cobalt is a ferromagnetic metallic element, and plays a dominant role in forming the magnetic crystal grains (minute magnets) in the in-plane magnetized film. From the viewpoint of increasing a crystal magnetic anisotropy constant Ku of CoPt alloy crystal grains (magnetic crystal grains) in the in-plane magnetized film obtained by sputtering and also from the viewpoint of maintaining the magnetization of the CoPt alloy crystal grains (magnetic crystal grains) in the in-plane magnetized film obtained, the content ratio of Co in the in-plane magnetized film 12 of the in-plane magnetized film multilayer structure 10 according to the present embodiment is set at 45 at % or more and 80 at % or less relative to the total of metal components of the in-plane magnetized film 12. From the similar viewpoint, the content ratio of Co in the in-plane magnetized film 12 of the in-plane magnetized film multilayer structure 10 according to the present embodiment is preferably 45 at % or more and 75 at % or less, and more preferably 45 at % or more and 70 at % or less, relative to the total of the metal components of the in-plane magnetized film 12.

Platinum is alloyed with Co in a predetermined composition range to have the function of reducing the magnetic moment of the alloy. As a result, it plays a role in controlling the strength of magnetism of the magnetic crystal grains. Moreover, Pt has the function of increasing a magnetic coercive force of the in-plane magnetized film by increasing a crystal magnetic anisotropy constant Ku of the CoPt alloy crystal grains (magnetic crystal grains) in the in-plane magnetized film obtained by sputtering. From the viewpoint of increasing the magnetic coercive force of the in-plane magnetized film and also from the viewpoint of controlling the magnetism of the CoPt alloy crystal grains (magnetic crystal grains) in the in-plane magnetized film, the content ratio of Pt in the in-plane magnetized film 12 of the in-plane magnetized film multilayer structure 10 according to the present embodiment is set at 20 at % or more and 55 at % or less relative to the total of the metal components of the in-plane magnetized film 12. From the similar viewpoint, the content ratio of Pt in the in-plane magnetized film 12 of the in-plane magnetized film multilayer structure 10 according to the present embodiment is preferably 25 at % or more and 55 at % or less, and more preferably 30 at % or more and 55 at % or less, relative to the total of the metal components of the in-plane magnetized film 12.

Further, as metal component of the in-plane magnetized film 12 of the in-plane magnetized film multilayer structure 10 according to the present embodiment, in addition to Co and Pt, boron B may be contained in an amount of 0.5 at % or more and 3.5 at % or less. As demonstrated in the examples to be described later, magnetic coercive force Hc of the in-plane magnetized film multilayer structure 10 can be further improved by containing boron B in an amount of 0.5 at % or more and 3.5 at % or less.

### (4) Nonmagnetic Intermediate Layer

The nonmagnetic intermediate layer 14 is interposed between the in-plane magnetized films 12, so as to playa role in separating the in-plane magnetized films 12 and multilayering the in-plane magnetized films 12. Multilayering the in-plane magnetized films 12 with the nonmagnetic intermediate layer 14 interposed therebetween can further increase the magnetic coercive force Hc while maintaining the value of the remanent magnetization Mrt.

The adjacent in-plane magnetized films 12 separated with the nonmagnetic intermediate layer 14 interposed therebetween are disposed so that spins are in parallel (directed in the same direction). Since disposing them in this manner allows the adjacent in-plane magnetized films 12 separated by the interposition of the nonmagnetic intermediate layer 14 to be coupled by a ferromagnetic coupling, the in-plane magnetized film 12 can further increase the magnetic coercive force Hc while maintaining the value of the remanent magnetization per unit area Mrt.

Therefore, the in-plane magnetized film multilayer structure 10 according to the present embodiment can exhibit a good magnetic coercive force Hc.

The metal used in the nonmagnetic intermediate layer 14 is preferably metal having the same crystal structure (hexagonal closest packed structure hcp) as the crystal structure of CoPt alloy magnetic crystal grains from the viewpoint of not impairing the crystal structure of the CoPt alloy magnetic crystal grains. Specifically, as the nonmagnetic intermediate layer 14, there may be suitably used metal Ru or a Ru alloy, which has the same crystal structure (hexagonal closest packed structure hcp) as the crystal structure of the CoPt alloy magnetic crystal grains in the in-plane magnetized film 12.

Specific examples of the additive element when the metal used in the nonmagnetic intermediate layer 14 is a Ru alloy may include Cr, Pt, and Co. The added amount of those metals is preferably in a range in which the Ru alloy takes a hexagonal closest packed structure hcp.

Bulk samples of a Ru alloy were produced by performing an arc welding, and X-ray diffraction peaks were analyzed by an X-ray diffraction device (XRD: SmartLab manufactured by Rigaku Corporation). In a RuCr alloy, when the added amount of Cr was 50 at %, a mixed phase of the hexagonal closest packed structure hcp and RuCr₂ was confirmed. Thus, when a RuCr alloy is used for the nonmagnetic interlayer 14, the added amount of Cr is suitably less than 50 at %, preferably less than 40 at %, and more preferably less than 30 at %. In a RuPt alloy, when the added amount of Pt was 15 at %, a mixed phase of the hexagonal closest packed structure hcp and a face-centered cubic structure fcc derived from Pt was confirmed. Thus, when a RuPt alloy is used for the nonmagnetic interlayer 14, the added amount of Pt is suitably less than 15 at %, preferably less than 12.5 at %, and more preferably less than 10 at %. In a RuCo alloy, regardless of the added amount of Co, the RuCo alloy forms the hexagonal closest packed structure hcp, but when adding Co in an amount of 40 at % or more, the RuCo alloy becomes a magnetic material. Thus, the added amount of Co is suitably less than 40 at %, preferably less than 30 at %, and more preferably less than 20 at %.

The thickness of the nonmagnetic intermediate layer 14 is typically 0.3 nm or more and 3 nm or less from the viewpoint of improving magnetic coercive force Hc of in-plane magnetized film multilayer structure 10. As demonstrated in examples 14 to 17 and comparative Example 14 described later, by multilayering CoPt in-plane magnetized film with a nonmagnetic intermediate layer made of metal Ru or a Ru alloy and having a thickness of 0.5 nm or more and 2 nm or less, the magnetic coercive force Hc can be improved by about 9 to 22% compared to the CoPt in-plane magnetized film single-layer structure (Comparative Example 14), and by multilayering with a nonmagnetic intermediate layer having a thickness of 1 nm or more and 2 nm or less, the magnetic coercive force Hc can be improved by about 16 to 22% compared to the CoPt in-plane magnetized film single-layer structure (Comparative Example 14), and by multilayering with a nonmagnetic intermediate layer having a thickness of 1.5 nm or more and 2 nm or less, the magnetic coercive force Hc can be improved by about 21 to 22% compared to the CoPt in-plane magnetized film single-layer structure (Comparative Example 14). Thus, the thickness of the nonmagnetic intermediate layer 14 is more preferably 1 nm or more and 2 nm or less, and particularly preferably 1.5 nm or more and 2 nm or less.

### (5) Substrate Film

As a substrate film used in forming the in-plane magnetized film 12 of the in-plane magnetized film multilayer structure 10 according to the present embodiment, a substrate film that is made of metal Ru or a Ru alloy having the same crystal structure (hexagonal closest packed structure hcp) as the crystal structure of the magnetic grains (CoPt alloy grains) of the in-plane magnetized film 12 is suitable.

To give a systematic in-plane orientation of the magnetic crystal grains (CoPt alloy grains) of the laminated in-plane magnetized film (CoPt-oxide) 12, it is preferable that a lot of (10.0) planes or (11.0) planes are disposed on a surface of the used Ru substrate film or Ru alloy substrate film.

The substrate film used in forming the in-plane magnetized film of the in-plane magnetized film multilayer structure according to the present invention is not limited to the Ru substrate film or Ru alloy substrate film, but any substrate film is usable as long as the substrate film is able to give the in-plane orientation of the CoPt magnetic crystal grains and to promote magnetic separation of the CoPt magnetic crystal grains in the obtained in-plane magnetized film.

### (6) Sputtering Target

A sputtering target used in producing the in-plane magnetized film 12 of the in-plane magnetized film multilayer structure 10 according to the present embodiment is a sputtering target that is used in producing the in-plane magnetized film 12 by room temperature film formation, where the in-plane magnetized film 12 is used as at least part of the hard bias layer 22 of the magnetoresistive effect element 20. The sputtering target contains metal Co and metal Pt. The sputtering target contains the metal Co in an amount of 55 at % or more and 80 at % or less and the metal Pt in an amount of 20 at % or more and 45 at % or less relative to the total of metal components of the sputtering target. The in-plane magnetized film to be formed can have a magnetic coercive force of 2.00 kOe or more, and remanent magnetization per unit area of 2.00 memu/cm² or more. As described in “(G) Analysis of composition of in-plane magnetized film (examples 10, 11, 12, and 13)” later, there is a deviation between the actual composition (composition obtained by an analysis of composition) of the produced CoPt-based in-plane magnetized film and the composition of the sputtering target used in producing the CoPt-based in-plane magnetized film, and so the composition range of each element contained in the above-described sputtering target is a composition range set in consideration of the deviation, and does not coincide with the composition range of each element contained in the in-plane magnetized film 12 of the in-plane magnetized film multilayer structure 10.

The room temperature film formation used herein refers to formation of a film without heating a substrate.

A description about components (metal Co and metal Pt) of the sputtering target is the same as that about the components of the in-plane magnetized film 12 described in the above-described “(3) In-plane magnetized film”, and so the description is omitted.

### (7) Method for Forming In-Plane Magnetized Film Multilayer Structure

The in-plane magnetized film multilayer structure 10 according to the present embodiment is formed as follows. The first layer of in-plane magnetized film 12 is formed on the substrate film described in “(5) Substrate film” above by sputtering using the sputtering target described in “(6) Sputtering target” above, and the nonmagnetic intermediate layer 14 described in “(4) Nonmagnetic intermediate layer” above is formed on the formed first layer of in-plane magnetized film 12 by sputtering. Then, the second layer of in-plane magnetized film 12 is formed on the formed nonmagnetic intermediate layer 14 by sputtering using sputtering target described in “(6) sputtering target” above. When the number of layers of in-plane magnetized film 12 of in-plane magnetized film multilayer structure 10 is three or more, the nonmagnetic intermediate layer 14 is formed on the second layer of in-plane magnetized film 12 by sputtering, and the third layer of in-plane magnetized film 12 is formed on the formed nonmagnetic intermediate layer 14 by sputtering using sputtering target described in “(6) sputtering target” above. Thereafter, this operation is repeated as many times as needed to form in-plane magnetized film multilayer structure 10 with the desired number of layers.

Note that, heating is unnecessary in any film formation process described in “(7) Method for forming in-plane magnetized film multilayer structure”, and the in-plane magnetized film multilayer structure 10 according to the present embodiment can be formed by room temperature film formation.

### EXAMPLES

Examples, Comparative Examples, and Reference Examples of an in-plane magnetized film multilayer structure containing CoPt in-plane magnetized films will be hereinafter described to verify the present invention. In the following (A), the composition ratios of Co and Pt, which are metal components of CoPt in-plane magnetized film constituting the in-plane magnetized film multilayer structure, and the effect of multilayering of CoPt in-plane magnetized film (when the total thickness is 30 nm) are studied; in the following (B), the effect of multilayering when the total thickness of CoPt in-plane magnetized film constituting the in-plane magnetized film multilayer structure is 60 nm is studied; in the following (C), the effect of multilayering when the total thickness of CoPt in-plane magnetized film constituting the in-plane magnetized film multilayer structure is 90 nm is studied; in the following (D), the thickness of the nonmagnetic intermediate layer constituting the in-plane magnetized film multilayer structure is studied; and in the following (E), the effect of adding boron (B) to CoPt in-plane magnetized film multilayer structure (when the total thickness is 60 nm) is studied. In the following (F), a single layer of CoPt in-plane magnetized film having the same thickness (15 nm) as that of CoPt alloy films described in Non-Patent Literature 1 and 2 is prepared by varying the Pt-composition, and the magnetic properties are measured.

In the following (G), analysis of composition was performed on CoPt in-plane magnetized films according to Examples 10, 11, 12, and 13 in order to check the degree of a deviation between the actual composition (composition obtained by the analysis of composition) of a produced CoPt in-plane magnetized film and the composition of a sputtering target used in producing the CoPt in-plane magnetized film. As a result, it was found out that a deviation occurred between the composition of an in-plane magnetized film and the composition of the sputtering target used in producing the in-plane magnetized film. Accordingly, the composition of CoPt in-plane magnetized films, except for the CoPt in-plane magnetized films according to Examples 10, 11, 12, and 13 the composition of which was actually analyzed, was calculated from the composition of sputtering targets used in production in consideration of the deviation that had been found out from a result of the analysis of composition of Examples 10, 11, 12, and 13, and assumed to be the composition of the CoPt in-plane magnetized film according to each example.

### (A) Study About Composition Ratio of Co and Pt Being Metal Components of CoPt In-Plane Magnetized Film Constituting In-Plane Magnetized Film Multilayer Structure and the Effect of Multilayering of CoPt In-Plane Magnetized Film (When the Total Thickness is 30 nm) (Examples 1 to 6 and Comparative Examples 1 to 11)

An in-plane magnetized film multilayer structure formed in each of Examples 1 to 6 and Comparative Example 1 is a multilayer structure in which CoPt in-plane magnetized films having a thickness of 15 nm are stacked in two layers sandwiching a Ru nonmagnetic intermediate layer having a thickness of 2.0 nm. In Examples 1 to 6 and Comparative Example 1, experimental data were obtained by varying the compositions of Co and Pt (Pt composition of the CoPt in-plane magnetized film was varied from 22.0 at % to 56.9 at %), which are the metal components of the CoPt in-plane magnetized films of the in-plane magnetized film multilayer structure.

Comparative Examples 2 to 11 are experimental examples in which single layers of CoPt in-plane magnetized films having a thickness of 30 nm were prepared by varying the Pt composition from 22.0 at % to 74.4 at %, and experimental data were obtained. The following is a specific explanation.

First, Ru substrate films were formed on a Si substrate using ES-3100W manufactured by EIKO ENGINEERING, LTD. by sputtering so as to have a thickness of 60 nm.

In Each of Examples 1 to 6 and Comparative Example 1, a CoPt in-plane magnetized film of a predetermined composition was formed on the formed Ru substrate film using the above-mentioned equipment ES-3100W by sputtering so as to have a thickness of 15 nm, and a Ru nonmagnetic intermediate layer was formed on the formed CoPt in-plane magnetized film having a thickness of 15 nm using the above-mentioned equipment ES-3100W by sputtering (using a sputtering target of 100 at % Ru) so as to have a thickness of 2.0 nm, and a CoPt in-plane magnetized film of the predetermined composition was formed on the formed Ru nonmagnetic intermediate layer using the above-mentioned equipment ES-3100W by sputtering so as to have a thickness of 15 nm. In Each of Comparative Examples 2 to 11, a CoPt in-plane magnetized film of a predetermined composition was formed on the formed Ru substrate film using the above-mentioned equipment ES-3100W by sputtering so as to have a thickness of 30 nm.

In these film formation processes (film formation processes of a Ru substrate film, a CoPt in-plane magnetized film, and a Ru nonmagnetic intermediate layer), none of them were subjected to substrate heating. They were performed in room temperature film formation. Note that, in any film formation process in examples and comparative examples of the present application, a sputtering apparatus used in sputtering is ES-3100W manufactured by EIKO ENGINEERING, LTD., and a description of the name of the apparatus will be omitted hereinbelow.

A hysteresis loop of each of the produced in-plane magnetized film multilayer structures in Examples 1 to 6 and Comparative Example 1 and in-plane magnetized film single-layer structures in Comparative Examples 2 to 11 was measured using a vibrating magnetometer (VSM: TM-VSM211483-HGC manufactured by TAMAKAWA CO., LTD.) (hereinafter referred to as a vibrating magnetometer). From the measured hysteresis loop, a magnetic coercive force Hc (kOe) and remanent magnetization Mr (memu/cm³) were read. By multiplying the read remanent magnetization Mr (memu/cm³) by the total thickness of the produced CoPt in-plane magnetized film, remanent magnetization per unit area Mrt (memu/cm²) was calculated. The results of Examples 1 to 6 and Comparative Examples 1 to 11 are shown in the following Table 1.

TABLE 1

| | Composition | | Composition | | Thickness of | | | |
|---|---|---|---|---|---|---|---|---|
| | of target | | of target | | in-plane | | | |
| | used for | Thickness of | used for | | magnetized | | Magnetic | Remanent |
| | producing | nonmagnetic | producing | Composition | film (nm) | | coercive | magnetization |
| | nonmagnetic | intermediate | in-plane | of in-plane | | Thickness | force | per unit area |
| | intermediate | layer | magnetized | magnetized | Total | of one | Hc | Mrt |
| | layer | (nm) | film | film | thickness | layer | (kOe) | (memu/cm²) |
| Example 1 | 100Ru | 2.0 | Co-20Pt | Co-22.0Pt | 30 | 15 | 3.08 | 2.58 |
| Example 2 | 100Ru | 2.0 | Co-25Pt | Co-27.8Pt | 30 | 15 | 4.11 | 2.62 |
| Example 3 | 100Ru | 2.0 | Co-30Pt | Co-33.7Pt | 30 | 15 | 5.50 | 2.30 |
| Example 4 | 100Ru | 2.0 | Co-35Pt | Co-39.5Pt | 30 | 15 | 7.16 | 2.20 |
| Example 5 | 100Ru | 2.0 | Co-40Pt | Co-45.3Pt | 30 | 15 | 6.62 | 2.11 |
| Example 6 | 100Ru | 2.0 | Co-45Pt | Co-51.1Pt | 30 | 15 | 6.56 | 2.03 |
| Comparative | 100Ru | 2.0 | Co-50Pt | Co-56.9Pt | 30 | 15 | 5.22 | 1.89 |
| Example 1 | | | | | | | | |
| Comparative | — | — | Co-20Pt | Co-22.0Pt | 30 | 30 | 2.25 | 2.63 |
| Example 2 | | | | | | | | |
| Comparative | — | — | Co-25Pt | Co-27.8Pt | 30 | 30 | 3.22 | 2.66 |
| Example 3 | | | | | | | | |
| Comparative | — | — | Co-30Pt | Co-33.7Pt | 30 | 30 | 4.93 | 2.29 |
| Example 4 | | | | | | | | |
| Comparative | — | — | Co-35Pt | Co-39.5Pt | 30 | 30 | 6.32 | 2.15 |
| Example 5 | | | | | | | | |
| Comparative | — | — | Co-40Pt | Co-45.3Pt | 30 | 30 | 6.93 | 1.91 |
| Example 6 | | | | | | | | |
| Comparative | — | — | Co-45Pt | Co-51.1Pt | 30 | 30 | 5.86 | 1.86 |
| Example 7 | | | | | | | | |
| Comparative | — | — | Co-50Pt | Co-56.9Pt | 30 | 30 | 4.75 | 1.77 |
| Example 8 | | | | | | | | |
| Comparative | — | — | Co-55Pt | Co-62.7Pt | 30 | 30 | 3.35 | 1.64 |
| Example 9 | | | | | | | | |
| Compa rative | — | — | Co-60Pt | Co-68.6Pt | 30 | 30 | 0.93 | 1.47 |
| Example 10 | | | | | | | | |
| Comparative | — | — | Co-65Pt | Co-74.4Pt | 30 | 30 | 0.29 | 1.38 |
| Example 11 | | | | | | | | |

Examples 1 to 6, each of which is an in-plane magnetized film multilayer structure in which CoPt in-plane magnetized films having a thickness of 15 nm are stacked in two layers sandwiching a Ru nonmagnetic intermediate layer having a thickness of 2.0 nm, and in which the content of Pt relative to the total of the metal components (Co and Pt) of the CoPt in-plane magnetized film is 22.0 to 51.1 at %, are within the scope of the present invention. As can be seen from Table 1, they achieved magnetic performance of a magnetic coercive force Hc of 2.00 kOe or more and remanent magnetization per unit area Mrt of 2.00 memu/cm² or more by the room temperature film formation without heating the substrate.

In contrast, comparative Example 1, which is the in-plane magnetized film multilayer structure in which CoPt in-plane magnetized films having a thickness of 15 nm are stacked in two layers sandwiching a Ru nonmagnetic intermediate layer having a thickness of 2.0 nm, but in which the content of Pt relative to the total of the metal components (Co and Pt) of the CoPt in-plane magnetized film is 56.9 at %, is not within the scope of the present invention. Comparative Example 1 has remanent magnetization per unit area Mrt of 1.89 memu/cm², which is less than 2.00 memu/cm².

Among Comparative Examples 2 to 11, which are the CoPt in-plane magnetized film single-layer structures having a thickness of 30 nm, and so are not included in the scope of the present invention, Comparative Examples 2 to 5 in which the content of Pt relative to the total of the metal components (Co and Pt) of the CoPt in-plane magnetized film is 22.0 to 39.5 at % achieved a magnetic performance in which magnetic coercive force Hc is 2.00 kOe or more and remanent magnetization per per unit area Mrt is 2.00 memu/cm² or more by the room temperature film formation without substrate heating, but their magnetic coercive force Hc was reduced by 10 to 27% as compared with Examples 1 to 4 having the same Pt content of CoPt in-plane magnetized film, respectively. Among Comparative Examples 2 to 11, which are the CoPt in-plane magnetized film single-layer structures having a thickness of 30 nm, and so are not included in the scope of the present invention, Comparative Examples 6 to 11 in which the content of Pt relative to the total of the metal components (Co and Pt) of the CoPt in-plane magnetized film is 45.3 to 74.4 at % had remanent magnetization per per unit area Mrt is 1.38 to 1.91 memu/cm², which is less than 2.00 memu/cm².

### (B) Study About the Effects of Multilayering of CoPt In-Plane Magnetized Films (When the Total Thickness is 60 nm) (Examples 7, 8, 17 and 9 and Comparative Examples 12 to 15)

An in-plane magnetized film multilayer structure formed in each of Examples 7, 8, 17 and 9 is a multilayer structure in which CoPt in-plane magnetized films having a thickness of 15 nm are stacked in four layers sandwiching a Ru nonmagnetic intermediate layer having a thickness of 2.0 nm. Examples 7, 8, 17 and 9 are experimental examples in which experimental data were obtained by varying the compositions of Co and Pt (Pt composition of the CoPt in-plane magnetized film was varied from 33.7 at % to 51.1 at %), which are the metal components of the CoPt in-plane magnetized films of the in-plane magnetized film multilayer structure having the above configuration.

Comparative Examples 12 to 15 are experimental examples in which single layers of CoPt in-plane magnetized films having a thickness of 60 nm were prepared by varying the Pt composition from 33.7 at % to 51.1 at %, and experimental data were obtained. The following is a specific explanation.

First, Ru substrate films were formed on Si substrates by sputtering so as to have a thickness of 60 nm.

In Each of Examples 7, 8, 17 and 9, a CoPt in-plane magnetized film of a predetermined composition was formed on the formed Ru substrate film by sputtering so as to have a thickness of 15 nm, and a Ru nonmagnetic intermediate layer was formed on the formed CoPt in-plane magnetized film having a thickness of 15 nm by sputtering (using a sputtering target of 100 at % Ru) so as to have a thickness of 2.0 nm, and a CoPt in-plane magnetized film of the predetermined composition was formed on the formed Ru nonmagnetic intermediate layer having a thickness of 2.0 nm by sputtering so as to have a thickness of 15 nm. The above operation was repeated to produce an in-plane magnetized film multilayer structure in which CoPt in-plane magnetized films of a predetermined composition are stacked in four layers. In Each of Comparative Examples 12 to 15, a single CoPt in-plane magnetized film of a predetermined composition was formed on the formed Ru substrate film by sputtering so as to have a thickness of 60 nm.

In these film formation processes (film formation processes of a Ru substrate film, a CoPt in-plane magnetized film, and a Ru nonmagnetic intermediate layer), none of them were subjected to substrate heating. They were performed in room temperature film formation.

A hysteresis loop of each of the produced in-plane magnetized film multilayer structures in Examples 7, 8, 17 and 9 and in-plane magnetized film single-layer structures in Comparative Examples 12 to 15 was measured using a vibrating magnetometer. From the measured hysteresis loop, a magnetic coercive force Hc (kOe) and remanent magnetization Mr (memu/cm³) were read. By multiplying the read remanent magnetization Mr (memu/cm³) by the total thickness of the produced CoPt in-plane magnetized films, remanent magnetization per unit area Mrt (memu/cm²) was calculated. The results of Examples 7, 8, 17 and 9 and Comparative Example 12 to 15 are shown in the following Table 2.

TABLE 2

| | Composition | | Composition | | Thickness of | | | |
|---|---|---|---|---|---|---|---|---|
| | of target | | of target | | in-plane | | | |
| | used for | Thickness of | used for | | magnetized | | Magnetic | Remanent |
| | producing | nonmagnetic | producing | Composition | film (nm) | | coercive | magnetization |
| | nonmagnetic | intermediate | in-plane | of in-plane | | Thickness | force | per unit area |
| | intermediate | layer | magnetized | magnetized | Total | of one | Hc | Mrt |
| | layer | (nm) | film | film | thickness | layer | (kOe) | (memu/cm²) |
| Example 7 | 100Ru | 2.0 | Co-30Pt | Co-33.7Pt | 60 | 15 | 4.76 | 4.99 |
| Example 8 | 100Ru | 2.0 | Co-35Pt | Co-39.5Pt | 60 | 15 | 5.84 | 4.60 |
| Example 17 | 100Ru | 2.0 | Co-40Pt | Co-45.3Pt | 60 | 15 | 5.68 | 4.20 |
| Example 9 | 100Ru | 2.0 | Co-45Pt | Co-51.1Pt | 60 | 15 | 5.02 | 4.09 |
| Comparative | — | — | Co-30Pt | Co-33.7Pt | 60 | 60 | 3.46 | 5.02 |
| Example 12 | | | | | | | | |
| Comparative | — | — | Co-35Pt | Co-39.5Pt | 60 | 60 | 4.80 | 4.52 |
| Example 13 | | | | | | | | |
| Comparative | — | — | Co-40Pt | Co-45.3Pt | 60 | 60 | 4.68 | 4.32 |
| Example 14 | | | | | | | | |
| Comparative | — | — | Co-45Pt | Co-51.1Pt | 60 | 60 | 4.05 | 4.16 |
| Example 15 | | | | | | | | |

As can be seen from Table 2, Examples 7, 8, 17 and 9, each of which is an in-plane magnetized film multilayer structure in which CoPt in-plane magnetized films having a thickness of 15 nm are stacked in four layers sandwiching a Ru nonmagnetic intermediate layer having a thickness of 2.0 nm, and in which the content of Pt relative to the total of the metal components (Co and Pt) of the CoPt in-plane magnetized film is 33.7 to 51.1 at %, are within the scope of the present invention, and they achieved magnetic performance of a magnetic coercive force Hc of 2.00 kOe or more and remanent magnetization per unit area Mrt of 2.00 memu/cm² or more by the room temperature film formation without heating the substrate.

In contrast, comparative Examples 12 to 15 are the in-plane magnetized film single-layer structures having a thickness of 60 nm, and so are not within the scope of the present invention. They have Pt in amount of 33.7 to 51.1 at % relative to the total of the metal components (Co and Pt) of the CoPt in-plane magnetized film. They achieved magnetic performance of a magnetic coercive force Hc of 2.00 kOe or more and remanent magnetization per unit area Mrt of 2.00 memu/cm² or more by the room temperature film formation without heating the substrate, but magnetic coercive force Hc was reduced by 18 to 27% as compared with Examples 7, 8, 17 and 9 having the same Pt content of CoPt in-plane magnetized film, respectively.

### (C) Study About the Effects of Multilayering of CoPt In-Plane Magnetized Films (When the Total Thickness is 90 nm) (Examples 10 to 13 and Comparative Examples 16 to 19)

An in-plane magnetized film multilayer structure formed in each of Examples 10 to 13 is a multilayer structure in which CoPt in-plane magnetized films having a thickness of 15 nm are stacked in six layers sandwiching a Ru nonmagnetic intermediate layer having a thickness of 2.0 nm. In Examples 10 to 13, experimental data were obtained by varying the compositions of Co and Pt (Pt composition of the CoPt in-plane magnetized film was varied from 33.7 at % to 51.1 at %), which are the metal components of the CoPt in-plane magnetized films of the in-plane magnetized film multilayer structure having the above configuration.

Comparative Examples 16 to 19 are experimental examples in which single layers of CoPt in-plane magnetized films having a thickness of 90 nm were prepared by varying the Pt composition from 33.7 at % to 51.1 at %, and experimental data were obtained. The following is a specific explanation.

First, Ru substrate films were formed on Si substrates by sputtering so as to have a thickness of 60 nm.

In Each of Examples 10 to 13, a CoPt in-plane magnetized film of a predetermined composition was formed on the formed Ru substrate film by sputtering so as to have a thickness of 15 nm, and a Ru nonmagnetic intermediate layer was formed on the formed CoPt in-plane magnetized film having a thickness of 15 nm by sputtering (using a sputtering target of 100 at % Ru) so as to have a thickness of 2.0 nm, and a CoPt in-plane magnetized film of the predetermined composition was formed on the formed Ru nonmagnetic intermediate layer having a thickness of 2.0 nm by sputtering so as to have a thickness of 15 nm. The above operation was repeated to produce an in-plane magnetized film multilayer structure in which CoPt in-plane magnetized films of a predetermined composition are stacked in six layers. In Each of Comparative Examples 16 to 19, a CoPt in-plane magnetized film of a predetermined composition was formed on the formed Ru substrate film by sputtering so as to have a thickness of 90 nm.

In these film formation processes (film formation processes of a Ru substrate film, a CoPt in-plane magnetized film, and a Ru nonmagnetic intermediate layer), none of them were subjected to substrate heating. They were performed in room temperature film formation.

A hysteresis loop of each of the produced in-plane magnetized film multilayer structures in Examples 10 to 13 and in-plane magnetized film single-layer structures in Comparative Examples 16-19 was measured using a vibrating magnetometer. From the measured hysteresis loop, a magnetic coercive force Hc (kOe) and remanent magnetization Mr (memu/cm³) were read. By multiplying the read remanent magnetization Mr (memu/cm³) by the total thickness of the produced CoPt in-plane magnetized film, remanent magnetization per unit area Mrt (memu/cm²) was calculated. The results of Examples 10 to 13 and Comparative Example 16 to 19 are shown in the following Table 3.

TABLE 3

| | Composition | | Composition | | Thickness of | | | |
|---|---|---|---|---|---|---|---|---|
| | of target | | of target | | in-plane | | | |
| | used for | Thickness of | used for | | magnetized | | Magnetic | Remanent |
| | producing | nonmagnetic | producing | Composition | film (nm) | | coercive | magnetization |
| | nonmagnetic | intermediate | in-plane | of in-plane | | Thickness | force | per unit area |
| | intermediate | layer | magnetized | magnetized | Total | of one | Hc | Mrt |
| | layer | (nm) | film | film | thickness | layer | (kOe) | (memu/cm²) |
| Example 10 | 100Ru | 2.0 | Co-30Pt | Co-33.7Pt | 90 | 15 | 4.08 | 7.89 |
| Example 11 | 100Ru | 2.0 | Co-35Pt | Co-39.5Pt | 90 | 15 | 5.03 | 7.02 |
| Example 12 | 100Ru | 2.0 | Co-40Pt | Co-45.3Pt | 90 | 15 | 4.90 | 6.41 |
| Example 13 | 100Ru | 2.0 | Co-45Pt | Co-51.1Pt | 90 | 15 | 4.23 | 6.16 |
| Comparative | — | — | Co-30Pt | Co-33.7Pt | 90 | 90 | 1.71 | 7.77 |
| Example 16 | | | | | | | | |
| Comparative | — | — | Co-35Pt | Co-39.5Pt | 90 | 90 | 1.73 | 7.23 |
| Example 17 | | | | | | | | |
| Comparative | — | — | Co-40Pt | Co-45.3Pt | 90 | 90 | 1.71 | 6.77 |
| Example 18 | | | | | | | | |
| Comparative | — | — | Co-45Pt | Co-51.1Pt | 90 | 90 | 1.72 | 6.28 |
| Example 19 | | | | | | | | |

As can be seen from Table 3, Examples 10 to 13, each of which is an in-plane magnetized film multilayer structure in which CoPt in-plane magnetized films having a thickness of 15 nm are stacked in six layers sandwiching a Ru nonmagnetic intermediate layer having a thickness of 2.0 nm, and in which the content of Pt relative to the total of the metal components (Co and Pt) of the CoPt in-plane magnetized film is 33.7 to 51.1 at %, are within the scope of the present invention, and they achieved magnetic performance of a magnetic coercive force Hc of 2.00 kOe or more and remanent magnetization per unit area Mrt of 2.00 memu/cm² or more by the room temperature film formation without heating the substrate.

In contrast, comparative Examples 16 to 19 are the in-plane magnetized film single-layer structure having a thickness of 90 nm, and so are not within the scope of the present invention. They have Pt in amount of 33.7 to 51.1 at % relative to the total of the metal components (Co and Pt) of the CoPt in-plane magnetized film. Their magnetic coercive force Hc were 1.71 to 1.73 kOe, which is less than 2.00 kOe.

### (D) Study About the Thickness of a Ru Nonmagnetic Intermediate Layer (Examples 14 to 17)

Examples 14 to 17 are experimental examples whose experimental data were obtained by varying a thickness of a Ru nonmagnetic intermediate layer from 0.5 nm to 2.0 nm in increments of 0.5 nm in in-plane magnetized film multilayer structures where CoPt in-plane magnetized films having a thickness of 15 nm are stacked in four layers sandwiching a Ru nonmagnetic intermediate layer. The following is a specific explanation.

First, Ru substrate films were formed on Si substrates by sputtering so as to have a thickness of 60 nm.

A CoPt in-plane magnetized film was formed on the formed Ru substrate film by sputtering so as to contain Pt in amount of 45.3 at % and have a thickness of 15 nm, and a Ru nonmagnetic intermediate layer was formed on the formed CoPt in-plane magnetized film having a thickness of 15 nm by sputtering (using a sputtering target of 100 at % Ru), and a CoPt in-plane magnetized film was formed on the formed Ru nonmagnetic intermediate layer by sputtering so as to contain Pt in amount of 45.3 at % and have a thickness of 15 nm. The above operation was repeated to produce an in-plane magnetized film multilayer structure in which CoPt in-plane magnetized films containing Pt in amount of 45.3 at % and having a thickness of 15 nm are stacked in four layers. The thickness of a Ru nonmagnetic intermediate layer is 0.5 nm (Example 14), 1.0 nm (Example 15), 1.5 nm (Example 16), and 2.0 nm (Example 17).

In these film formation processes (film formation processes of a Ru substrate film, a CoPt in-plane magnetized film, and a Ru nonmagnetic intermediate layer), none of them were subjected to substrate heating. They were performed in room temperature film formation.

A hysteresis loop of each of the produced in-plane magnetized film multilayer structures in Examples 14 to 17 was measured using a vibrating magnetometer. From the measured hysteresis loop, a magnetic coercive force Hc (kOe) and remanent magnetization Mr (memu/cm³) were read. By multiplying the read remanent magnetization Mr (memu/cm³) by the total thickness of the produced CoPt in-plane magnetized film, remanent magnetization per unit area Mrt (memu/cm²) was calculated. The results of Examples 14 to 17 are shown in the following Table 4 with the result of Comparative Example 14 described in the above (B). Comparative Example 14 is an experimental example in which a Ru nonmagnetic intermediate layer is not formed, and is an experimental example of CoPt in-plane magnetized film single-layer structure containing Pt in amount of 45.3 at % and having a thickness of 60 nm.

TABLE 4

| | Composition | | Composition | | Thickness of | | | |
|---|---|---|---|---|---|---|---|---|
| | of target | | of target | | in-plane | | | |
| | used for | Thickness of | used for | | magnetized | | Magnetic | Remanent |
| | producing | nonmagnetic | producing | Composition | film (nm) | | coercive | magnetization |
| | nonmagnetic | intermediate | in-plane | of in-plane | | Thickness | force | per unit area |
| | intermediate | layer | magnetized | magnetized | Total | of one | Hc | Mrt |
| | layer | (nm) | film | film | thickness | layer | (kOe) | (memu/cm²) |
| Example 14 | 100Ru | 0.5 | Co-40Pt | Co-45.3Pt | 60 | 15 | 5.10 | 4.37 |
| Example 15 | 100Ru | 1.0 | Co-40Pt | Co-45.3Pt | 60 | 15 | 5.44 | 4.28 |
| Example 16 | 100Ru | 1.5 | Co-40Pt | Co-45.3Pt | 60 | 15 | 5.69 | 4.21 |
| Example 17 | 100Ru | 2.0 | Co-40Pt | Co-45.3Pt | 60 | 15 | 5.68 | 4.20 |
| Comparative | — | — | Co-40Pt | Co-45.3Pt | 60 | 60 | 4.68 | 4.32 |
| Example 14 | | | | | | | | |

As can be seen from Table 4, in Examples 14 to 17 in which multilayering of the CoPt in-plane magnetized films were performed by providing Ru nonmagnetic intermediate layers having a thickness of 0.5 to 2.0 nm, magnetic coercive force Hc is improved by about 9 to 22% as compared with Comparative Example 14 in which a Ru nonmagnetic intermediate layer is not provided and the CoPt in-plane magnetized film is a single layer. In contrast, remanent magnetization per unit area Mrt (memu/cm²) is roughly equivalent to that of Comparative Example 14.

Therefore, by multilayering CoPt in-plane magnetized film with Ru nonmagnetic intermediate layers having the thickness of 0.5 to 2.0 nm, magnetic coercive force Hc can be improved by about 9 to 22% while maintaining remanent magnetization per unit area Mrt (memu/cm²). Therefore, it is considered preferable that the thickness of the Ru nonmagnetic intermediate layer for multilayering CoPt in-plane magnetized film is 0.5 to 2.0 nm.

In Examples 14 to 17 in which multilayering of the CoPt in-plane magnetized film was performed by providing Ru nonmagnetic intermediate layers, the thickness of the Ru nonmagnetic intermediate layer was varied from 0.5 to 2.0 nm. Compared with in Example 14 in which the thickness of the Ru nonmagnetic intermediate layer was 0.5 nm, in Examples 15 to 17 in which the thickness of the Ru nonmagnetic intermediate layers was 1.0 to 2.0 nm, magnetic coercive force Hc was improved by about 7 to 12%, and in Examples 16 and 17 in which the thickness of the Ru nonmagnetic intermediate layers was 1.5 nm and 2.0 nm, magnetic coercive force Hc was improved by about 11 to 12%. In contrast, for the remanent magnetization Mrt per unit area (memu/cm²), the difference in Examples 14-17 is about 4% at most. Therefore, it is considered that the thickness of Ru nonmagnetic intermediate layers for multilayering CoPt in-plane magnetized film is more preferably 1.0 to 2.0 nm, and particularly preferably 1.5 to 2.0 nm.

### (E) Study About the Effects of Adding Boron (B) to CoPt In-Plane Magnetized Film Multilayer Structures (When the Total Thickness is 60 nm) (Examples 18 to 20)

Examples 18 to 20 are experimental examples whose experimental data were obtained by varying the content of B to the total of metal components of CoPtB in-plane magnetized films (the total of Co, Pt, and B) in the order of 1.0 at %, 2.0 at %, and 3.0 at % in in-plane magnetized film multilayer structures where the CoPt in-plane magnetized films having a thickness of 15 nm are stacked in four layers sandwiching the Ru nonmagnetic intermediate layer. The following is a specific explanation.

First, Ru substrate films were formed on Si substrates by sputtering so as to have a thickness of 60 nm.

A CoPtB in-plane magnetized film was formed on the formed Ru substrate film by sputtering so as to contain Pt in amount of 45.3 at % and have a thickness of 15 nm, and a Ru nonmagnetic intermediate layer having a thickness of 2.0 nm was formed on the formed CoPtB in-plane magnetized film having a thickness of 15 nm by sputtering (using a sputtering target of 100 at % Ru), and a CoPtB in-plane magnetized film was formed on the formed Ru nonmagnetic intermediate layer by sputtering so as to contain Pt in amount of 45.3 at % and have a thickness of 15 nm. The above operation was repeated to produce the in-plane magnetized film multilayer structures in which CoPtB in-plane magnetized films containing Pt in amount of 45.3 at % and having a thickness of 15 nm are stacked in four layers. The content of B to the total of metal components of CoPtB in-plane magnetized film (the total of Co, Pt, and B) is 1.0 at % (Example 18), 2.0 at % (Example 19), and 3.0 at % (Example 20).

In these film formation processes (film formation processes of a Ru substrate film, a CoPtB in-plane magnetized film, and a Ru nonmagnetic intermediate layer), none of them were subjected to substrate heating. They were performed in room temperature film formation.

A hysteresis loop of each of the produced in-plane magnetized film multilayer structures in Examples 18 to 20 was measured using a vibrating magnetometer. From the measured hysteresis loop, a magnetic coercive force Hc (kOe) and remanent magnetization Mr (memu/cm³) were read. By multiplying the read remanent magnetization Mr (memu/cm³) by the total thickness of the produced CoPt in-plane magnetized film, remanent magnetization per unit area Mrt (memu/cm²) was calculated. The results of Examples 18 to 20 are shown in the following Table 5 with the result of Example 17 described in the above (D). Example 17 is an experimental example in which B is not added to the CoPt in-plane magnetized film of the in-plane magnetized film multilayer structure, and is an experimental example of the CoPt in-plane magnetized film multilayer structure in which Co-45.3Pt in-plane magnetized films having a thickness of 15 nm are stacked in four layers sandwiching a Ru nonmagnetic intermediate layer having a thickness of 2.0 nm.

TABLE 5

| | Composition | | Composition | | Thickness of | | | |
|---|---|---|---|---|---|---|---|---|
| | of target | | of target | | in-plane | | | |
| | used for | Thickness of | used for | | magnetized | | Magnetic | Remanent |
| | producing | nonmagnetic | producing | Composition | film (nm) | | coercive | magnetization |
| | nonmagnetic | intermediate | in-plane | of in-plane | | Thickness | force | per unit area |
| | intermediate | layer | magnetized | magnetized | Total | of one | Hc | Mrt |
| | layer | (nm) | film | film | thickness | layer | (kOe) | (memu/cm²) |
| Example 18 | 100Ru | 2.0 | (Co-40Pt) | (Co-45.3Pt) | 60 | 15 | 5.82 | 4.19 |
| | | | −1.0B | −1.0B | | | | |
| Example 19 | 100Ru | 2.0 | (Co-40Pt) | (Co-45.3Pt) | 60 | 15 | 5.98 | 4.14 |
| | | | −2.0B | −2.0B | | | | |
| Example 20 | 100Ru | 2.0 | (Co-40Pt) | (Co-45.3Pt) | 60 | 15 | 5.88 | 4.16 |
| | | | −3.0B | −3.0B | | | | |
| Example 17 | 100Ru | 2.0 | Co-40Pt | Co-45.3Pt | 60 | 15 | 5.68 | 4.20 |

As can be seen from Table 5, in Examples 18 to 20 in which boron B was added to the CoPt in-plane magnetized film of CoPt in-plane magnetized film multilayer structures showed an improvement in magnetic coercive force Hc of about 2.5% to 5.3% compared to Example 17 in which boron B was not added to the CoPt in-plane magnetized film of the CoPt in-plane magnetized film multilayer structure. In contrast, remanent magnetization per unit area Mrt (memu/cm²) is roughly equivalent to that of Example 17.

Therefore, by adding boron B to the CoPt in-plane magnetized film of CoPt in-plane magnetized film multilayer structures, magnetic coercive force Hc can be improved by about 2.5% to 5.3% while maintaining remanent magnetization per unit area Mrt (memu/cm²).

### (F) Study About CoPt In-Plane Magnetized Film Single-Layer Structures Having a Thickness of 15 nm (Comparative Examples 20 to 29)

Single layers of CoPt in-plane magnetized films having the same thickness (15 nm) as CoPt alloy film described in Non-Patent Literature 1 and 2 were prepared by varying the Pt composition from 22.0 at % to 74.4 at %, and experimental data were obtained. The following is a specific explanation.

First, Ru substrate films were formed on Si substrates by sputtering so as to have a thickness of 60 nm.

CoPt in-plane magnetized single-layer films of a predetermined composition were formed on the formed Ru substrate film by sputtering so as to have a thickness of 15 nm.

In these film formation processes (film formation processes of a Ru substrate film and a CoPt in-plane magnetized film), none of them were subjected to substrate heating. They were performed in room temperature film formation.

A hysteresis loop of each of the produced CoPt in-plane magnetized film single-layer structures having a thickness of 15 nm in Comparative Examples 20 to 29 was measured using a vibrating magnetometer. From the measured hysteresis loop, a magnetic coercive force Hc (kOe) and remanent magnetization Mr (memu/cm³) were read. By multiplying the read remanent magnetization Mr (memu/cm³) by the total thickness of the produced CoPt in-plane magnetized film, remanent magnetization per unit area Mrt (memu/cm²) was calculated. The results of Comparative Example 20 to 29 are shown in the following Table 6.

TABLE 6

| | Composition | | Composition | | Thickness of | | | |
|---|---|---|---|---|---|---|---|---|
| | of target | | of target | | in-plane | | | |
| | used for | Thickness of | used for | | magnetized | | Magnetic | Remanent |
| | producing | nonmagnetic | producing | Composition | film (nm) | | coercive | magnetization |
| | nonmagnetic | intermediate | in-plane | of in-plane | | Thickness | force | per unit area |
| | intermediate | layer | magnetized | magnetized | Total | of one | Hc | Mrt |
| | layer | (nm) | film | film | thickness | layer | (kOe) | (memu/cm²) |
| Comparative | — | — | Co-20Pt | Co-22.0Pt | 15 | 15 | 2.83 | 1.21 |
| Example 20 | | | | | | | | |
| Comparative | — | — | Co-25Pt | Co-27.8Pt | 15 | 15 | 6.56 | 1.21 |
| Example 21 | | | | | | | | |
| Comparative | | | Co-30Pt | Co-33.7Pt | 15 | 15 | 5.71 | 1.05 |
| Example 22 | — | — | | | | | | |
| Comparative | | | Co-35Pt | Co-39.5Pt | 15 | 15 | 7.28 | 0.94 |
| Example 23 | — | — | | | | | | |
| Comparative | | | Co-40Pt | Co-45.3Pt | 15 | 15 | 8.23 | 0.90 |
| Example 24 | — | — | | | | | | |
| Comparative | | | Co-45Pt | Co-51.1Pt | 15 | 15 | 8.35 | 0.82 |
| Example 25 | — | — | | | | | | |
| Comparative | | | Co-50Pt | Co-56.9Pt | 15 | 15 | 7.00 | 0.78 |
| Example 26 | — | — | | | | | | |
| Comparative | | | Co-55Pt | Co-62.7Pt | 15 | 15 | 4.80 | 0.73 |
| Example 27 | — | — | | | | | | |
| Comparative | | | Co-60Pt | Co-68.6Pt | 15 | 15 | 2.39 | 0.68 |
| Example 28 | — | — | | | | | | |
| Comparative | | | Co-65Pt | Co-74.4Pt | 15 | 15 | 0.67 | 0.60 |
| Example 29 | | | | | | | | |

As can be seen from Table 6, among Comparative Examples 20 to 29, each of which is an in-plane magnetized film single-layer structure having a thickness of 15 nm and containing Pt in amount of 22.0 to 74.4 at % relative to the total of the metal components (Co and Pt) of the CoPt in-plane magnetized film, and which are not within the scope of the present invention, Comparative Examples 20 to 28 containing Pt in amount of 22.0 to 68.6 at % achieved magnetic performance of a magnetic coercive force Hc of 2.00 kOe or more by the room temperature film formation without heating the substrate, but their remanent magnetization per unit area Mrt was less than 2.00 memu/cm². Comparative Example 29 containing Pt in amount of 74.4 at % not only has remanent magnetization per unit area Mrt of less than 2.00 memu/cm², but also a magnetic coercive force Hc of less than 2.00 kOe.

Therefore, the CoPt alloy films having a thickness of 15 nm described in Non-Patent Literature 1 and 2 are considered to satisfy magnetic performance of magnetic coercive force Hc of 2.00 kOe or more depending on the Pt content, but are considered to be less than 2.00 memu/cm² of remanent magnetization regardless of the Pt content.

### (G) Analysis of Composition of In-Plane Magnetized Films (Examples 10, 11, 12, and 13)

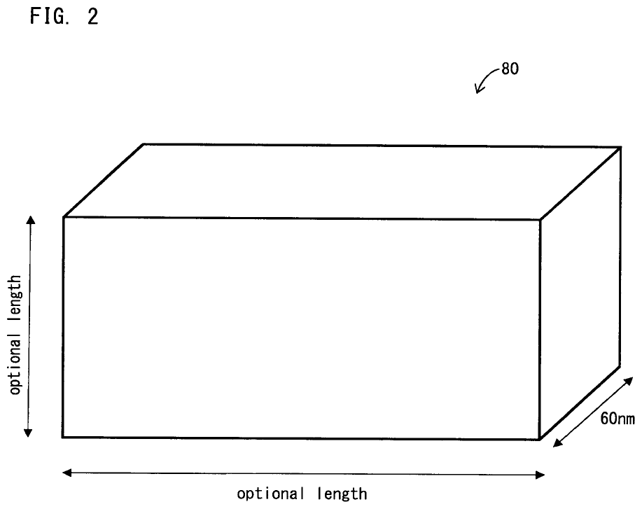

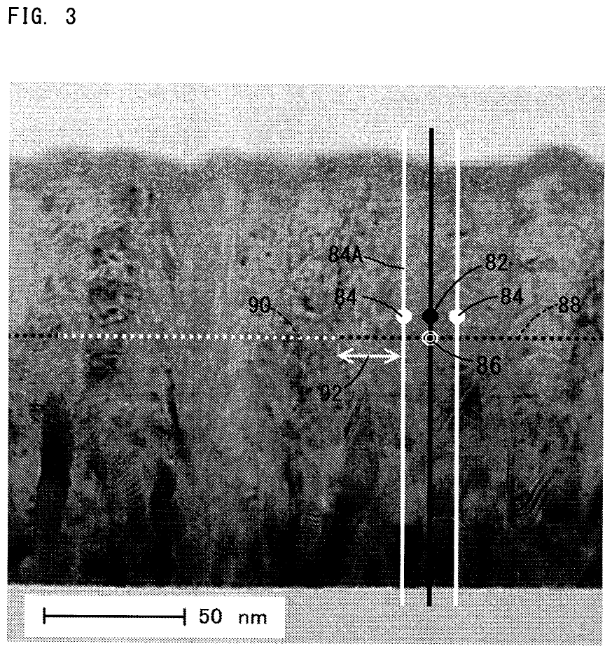

The compositions of the in-plane magnetized films of the in-plane magnetized film multilayer structures of Examples 10, 11, 12, and 13 were analyzed. The in-plane magnetized film multilayer structures of Examples 10, 11, 12, and 13 are in-plane magnetized film multilayer structures in which CoPt in-plane magnetized films having a thickness of 15 nm are stacked in six layers sandwiching a Ru nonmagnetic intermediate layer having a thickness of 2 nm. An outline of steps of a composition analysis method performed will be described, and thereafter concrete contents of each step will further be described.

[Outline of steps] Line analysis is performed to analyze the composition in a thickness direction of an in-plane magnetized film, and a portion having less variation in the composition is chosen from linearly analyzed portions in cross section in the thickness direction of the in-plane magnetized film (Steps 1 to 4). Then, auxiliary lines are drawn to the left and right in the in-plane direction of the in-plane magnetized film to be analyzed for composition so as to include an optional measurement point included in the portion having less variation in the composition, and line analysis is performed to analyze the composition in a linear region of 100 nm (167 measurement points) on the auxiliary lines (Step 5). An average value of detected strengths at 167 measurement points is calculated on each detected element, to determine the composition of the in-plane magnetized film (Step 6). Steps 1 to 6 will be hereinafter described in the concrete.

[Step 1] An in-plane magnetized film the composition of which was to be analyzed is cut by parallel two planes in a direction (a thickness direction of the in-plane magnetized film) orthogonal to an in-plane direction, and thinning processing is performed by a FIB method (μ-sampling method) until the distance between the obtained two parallel cutting planes becomes about 60 nm. FIG. 2 schematically shows the shape of a thinned sample 80 after having been subjected to the thinning processing. As shown in FIG. 2, the shape of the thinned sample 80 is in an approximately rectangular parallelepiped shape. The distance between the two parallel cutting planes is about 60 nm, and the length of a side of the rectangular parallelepiped thinned sample 80 in the in-plane direction is about 60 nm, but the lengths of other two sides may be appropriately determined as long as the thinned sample 80 is observable by a scanning transmission electron microscope.

[Step 2] The cutting plane (the cutting plane of the in-plane magnetized film in the thickness direction) of the thinned sample 80 obtained in Step 1 is imaged using the scanning transmission electron microscope that allows observation with magnifying a length of 100 nm into 2 cm (observation at a magnification of two hundred thousand times), and an observation image is captured. The rectangular observation image is captured such that a line of a crossing portion of a topmost surface of the in-plane magnetized film to be observed and the cutting plane (the cutting plane in the thickness direction of the in-plane magnetized film) coincides with a longitudinal direction of the rectangular observation image. FIG. 3 shows an example (observation image of Example 10) of the captured observation image. The observation image of the in-plane magnetized film was captured using H-9500 manufactured by Hitachi High-Tech Corporation.

[Step 3] An optional point (indicated by a black dot 82 in FIG. 3) included in the in-plane magnetized film is chosen from the observation image captured in Step 2, and positions (indicated by white dots 84 in FIG. 3) 10 nm away from the point to left and right in the longitudinal direction of the observation image are pointed. Line analysis for elemental analysis is performed in the thickness direction of the in-plane magnetized film so as to pass the point of the black dot 82, and line analysis for elemental analysis is performed in the thickness direction of the in-plane magnetized film so as to pass the points of the white dots 84. Thereby, line analysis (scanning from top to bottom) for elemental analysis is performed in the thickness direction of the in-plane magnetized film with respect to three lines (one line passing through the black dot 82 in the thickness direction and two lines passing through the white dots 84 in the thickness direction). At the time of performing the line analysis for elemental analysis, it is necessary to choose the point of the one black dot 82 and the points of the two white dots 84 such that a scanning range of the line analysis along the three lines corresponds to the entire range in the thickness direction of the in-plane magnetized film (when a target of composition analysis is an in-plane magnetized film multilayer structure, it is the entire range from an uppermost in-plane magnetized film to a lowermost in-plane magnetized film), in principle.

In composition analysis of the in-plane magnetized film, energy dispersive X-ray spectroscopy (EDX) was adopted as an element analysis technique, and JEM-ARM200F manufactured by JEOL Ltd. was used as an elemental analyzer. Concrete analysis conditions were as follows. That is, a Si-drift detector was used as an X-ray detector, an X-ray take-off angle was 21.9°, a solid angle was approximately 0.98 sr, a dispersive crystal generally appropriate to each element was used, a measurement time was 1 seconds/point, a scanning interval was 0.6 nm, and an irradiation beam diameter was 0.2 nmΦ. The conditions described in this paragraph may be hereinafter referred to as “analysis conditions of Step 3”.

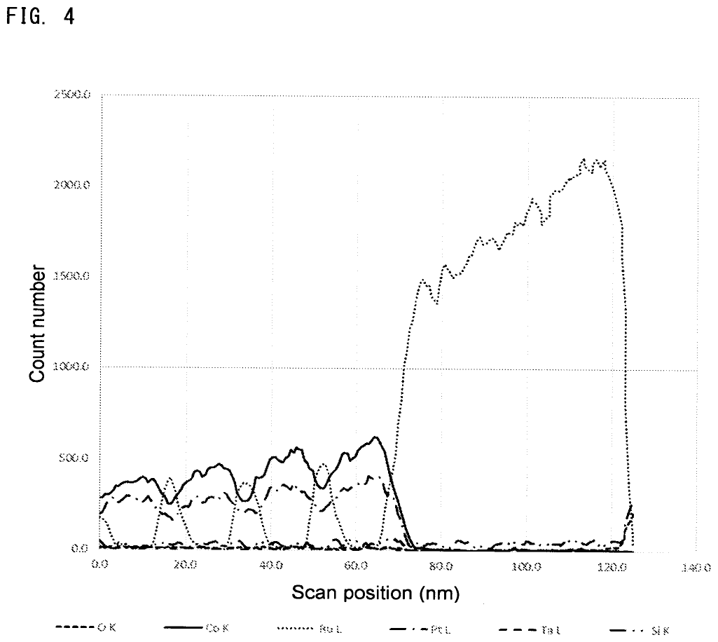

FIG. 4 shows a result of the line analysis (elemental analysis) performed along a black line (the line passing through the point of the black dot in the thickness direction of the in-plane magnetized film) in FIG. 3 (the observation image of Example 10). In FIG. 4, a vertical axis represents a count number indicating the detection strength of each element, and a horizontal axis represents a scan position. Elements shown in an explanatory note of FIG. 4 are elements that have been confirmed with sufficient detection strengths. In Example 10, the elements confirmed with sufficient detection strengths were Co, Pt, and Ru. In the composition analysis of Example 10, a Kα1-ray was chosen to detect Co, and a Lα1-ray was chosen to detect Pt and Ru. Each detection strength was corrected by subtracting a detection strength of blank measurement measured in advance. In FIG. 3, a last end (lowermost end) of the line analysis is a Si substrate. In this portion, only Si and O which is due to surface oxidation are detected in theory. Accordingly, a detection value of an element other than Si and O detected in this portion is conceivable to be an unavoidable detection error value in the elemental analyzer. Thus, the detection strength shall represent the presence of the element only when the detection strength is higher than the detection error value. Further, in the composition analysis range of the elemental analyzer used in Step 3, because the line analysis covering the entire range from Si substrate to the oxidation protective layer provided on the in-plane magnetized film can not be performed by a single line analysis, only the result when the measurement is started from around the fourth layer from the bottom of the six-layer stacked in-plane magnetized film and scanned downward is shown in FIG. 4. Because the production process of in-plane magnetized film in which the six-layer stacked is the same, it is considered that the same composition in any in-plane magnetized film of the six-layer stacked. Therefore, the line analysis of in-plane magnetized film portions located above the measured portions are omitted.

In Example 10 having an in-plane magnetized film multilayer structure, in-plane magnetized films (the composition is Co-33.7Pt) each of which had a thickness of 15 nm were formed using a sputtering target having a composition of Co-30Pt. Also, metal Ru nonmagnetic intermediate layers each of which had a thickness of 2 nm between the in-plane magnetized films were formed to be positioned between the in-plane magnetized films. To form the metal Ru nonmagnetic intermediate layers, a sputtering target having a composition of 100 at % Ru was used.

As can be seen from the result of line analysis shown in FIG. 4, Co and Pt were mainly detected in the in-plane magnetized films, and Ru was mainly detected in the nonmagnetic intermediate layers. In the metal Ru nonmagnetic intermediate layers, detection strengths based on the constituent elements of the in-plane magnetized films are partly detected. This is because the elements of each of upper and lower adjacent layers are slightly diffused by sputtering heat during film formation. However, as far as seen from the distribution of each primary element of the in-plane magnetized films and the nonmagnetic intermediate layers, it was confirmed that film formation was performed as almost designed.

[Step 4] From the result of the line analysis (the line analysis for elemental analysis performed in the thickness direction of the in-plane magnetized film) performed in Step 3, an aggregation portion of measurement points having less variation in composition is chosen. The aggregation portion of the measurement points having less variation in composition is an aggregation portion of measurement points satisfying the following conditions a to c.

Condition a) The measurement points are measurement points of the line analysis along any of the three lines performed in Step 3, and where the sum of the detection strengths of Co and Pt exceeds 600 counts.

Condition b) When an X count represents the sum of the detection strengths of Co and Pt at the measurement point, and a Y count represents the sum of the detection strengths of Co and Pt at the next measurement point (a measurement point that is adjacent to and 0.6 nm downward away from the measurement point) after measurement is performed at the measurement point,

Y/X−1<0.05

is satisfied.

Condition c) The measurement points are five or more consecutive measurement points that satisfy the conditions a and b.

The aggregation portion of the measurement points satisfying the conditions a to c contains five or more consecutive measurement points, and hence is in a linear area of 0.6 nm×4=2.4 nm or more. Therefore, the aggregation portion of the measurement points satisfying the conditions a to c is a linear area of a range of 2.4 nm or more in which at least one of Co or Pt is stably detected.

[Step 5] An optional measurement point is chosen from the aggregation of the measurement points chosen in Step 4, as a reference point (indicated by a double white circle 86 in FIG. 3) for composition analysis of the in-plane magnetized film. Then, an auxiliary line (indicated by black broken line 88 in FIG. 3) is drawn to the left and right in the in-plane direction (longitudinal direction of observation image in FIG. 3) of in-plane magnetized film in which the composition analysis is performed so as to include the reference point, and the composition analysis is performed on a linear area of 100 nm (indicated by white broken line 90 in FIG. 3) on the auxiliary line under the same analysis conditions as that in Step 3. In order to avoid contamination caused by the above-mentioned line analysis in the thickness direction, white broken line 90, which is a target portion of the composition analysis, was set at a distance (indicated by white line 92 with arrows attached to both ends in FIG. 3) of 10 nm or more from the line analysis portion (white line 84A in FIG. 3) in the thickness direction. In the composition analysis, because line analysis is performed on the linear area of 100 nm at scanning intervals of 0.6 nm, analysis results are obtained at 167 measurement points in total.

[Step 6] An average value of detected strengths (count numbers) of 167 measurement points is calculated on each detected element. The ratio of the average values of the detected strengths (count numbers) of each detected elements coincides with the composition ratio of each element of the in-plane magnetized film.

In Example 18, 19, and 20, boron (B) is added to the in-plane magnetized film, but boron (B) cannot be detected in analysis by EDX because boron (B) is a light element having a small atomic number. Therefore, in the composition of the in-plane magnetized film according to Example 18, 19, and 20, though the composition ratio of Co and Pt can be determined, the content of B cannot be determined.

In FIG. 3, circles, straight lines, etc. indicated by the reference signs 82, 84, 84A, 86, 88, 90, and 92 are added for convenience in explaining the composition analysis method, and do not correspond to the actual measurement portion.

### INDUSTRIAL APPLICABILITY

The in-plane magnetized film multilayer structure, the hard bias layer, and the magnetoresistive effect element according to the present invention can achieve magnetic performance of a magnetic coercive force Hc of 2.00 kOe or more and remanent magnetization per unit area Mrt of 2.00 memu/cm² or more, without performing film formation with heating, and hence have industrial applicability.

### REFERENCE SIGNS LIST

10 in-plane magnetized film multilayer structure

12 in-plane magnetized film

14 nonmagnetic intermediate layer

20 magnetoresistive effect element

22 hard bias layer

24 free magnetic layer

50 insulating layer

52 pinned layer

54 barrier layer

80 thinned sample

82 black dot (optional point included in in-plane magnetized film)

84 white dot (points at positions 10 nm away from black dot 82 to left and right in longitudinal direction of observation image)

84A white line

86 double white circle (reference point for composition analysis of in-plane magnetized film)

88 black broken line (an auxiliary line drawn from double white circle 86 (reference point) in longitudinal direction of observation image)

90 white broken line (100 nm linear area on black broken line 88 (auxiliary line))

92 white line with arrows at both ends (indicating distances of 10 nm or more from white line 84A)

1. An in-plane magnetized film multilayer structure for use as a hard bias layer of a magnetoresistive effect element, the in-plane magnetized film multilayer structure comprising:
a plurality of in-plane magnetized films; and
a nonmagnetic intermediate layer, wherein
the nonmagnetic intermediate layer is disposed between the in-plane magnetized films, and the in-plane magnetized films adjacent across the nonmagnetic intermediate layer are coupled by a ferromagnetic coupling,
each of the in-plane magnetized films
contains metal Co and metal Pt, and
contains the metal Co in an amount of 45 at % or more and 80 at % or less and the metal Pt in an amount of 20 at % or more and 55 at % or less relative to a total of metal components of the each of the in-plane magnetized films, and
a total thickness of the plurality of in-plane magnetized films is 30 nm or more.

2. An in-plane magnetized film multilayer structure for use as a hard bias layer of a magnetoresistive effect element, the in-plane magnetized film multilayer structure comprising:
a plurality of in-plane magnetized films; and
a nonmagnetic intermediate layer, wherein
the nonmagnetic intermediate layer is disposed between the in-plane magnetized films, and the in-plane magnetized films adjacent across the nonmagnetic intermediate layer are coupled by a ferromagnetic coupling,
each of the in-plane magnetized films
contains metal Co and metal Pt, and
contains the metal Co in an amount of 45 at % or more and 80 at % or less and the metal Pt in an amount of 20 at % or more and 55 at % or less relative to a total of metal components of the each of the in-plane magnetized films, and
the in-plane magnetized film multilayer structure has a magnetic coercive force of 2.00 kOe or more and remanent magnetization per unit area of 2.00 memu/cm² or more.

3. The in-plane magnetized film multilayer structure according to claim 1, wherein each of the in-plane magnetized films contains boron in an amount of 0.5 at % or more and 3.5 at % or less relative to a total of metal components of the each of the in-plane magnetized films.

4. The in-plane magnetized film multilayer structure according to claim 1, wherein a thickness of the nonmagnetic intermediate layer is 0.3 nm or more and 3 nm or less.

5. The in-plane magnetized film multilayer structure according to claim 1, wherein the nonmagnetic intermediate layer is made of Ru or a Ru alloy.

6. The in-plane magnetized film multilayer structure according to claim 1, wherein a thickness per one layer of the in-plane magnetized films is 5 nm or more and 30 nm or less.

7. A hard bias layer comprising the in-plane magnetized film multilayer structure according to claim 1.

8. A magnetoresistive effect element comprising the hard bias layer according to claim 7.

9. The in-plane magnetized film multilayer structure according to claim 2, wherein each of the in-plane magnetized films contains boron in an amount of 0.5 at % or more and 3.5 at % or less relative to a total of metal components of the each of the in-plane magnetized films.

10. The in-plane magnetized film multilayer structure according to claim 2, wherein a thickness of the nonmagnetic intermediate layer is 0.3 nm or more and 3 nm or less.

11. The in-plane magnetized film multilayer structure according to claim 3, wherein a thickness of the nonmagnetic intermediate layer is 0.3 nm or more and 3 nm or less.

12. The in-plane magnetized film multilayer structure according to claim 9, wherein a thickness of the nonmagnetic intermediate layer is 0.3 nm or more and 3 nm or less.

13. The in-plane magnetized film multilayer structure according to claim 2, wherein the nonmagnetic intermediate layer is made of Ru or a Ru alloy.

14. The in-plane magnetized film multilayer structure according to claim 2, wherein a thickness per one layer of the in-plane magnetized films is 5 nm or more and 30 nm or less.

15. A hard bias layer comprising the in-plane magnetized film multilayer structure according to claim 2.

16. A hard bias layer comprising the in-plane magnetized film multilayer structure according to claim 4.

17. A hard bias layer comprising the in-plane magnetized film multilayer structure according to claim 10.

18. A magnetoresistive effect element comprising the hard bias layer according to claim 15.

19. A magnetoresistive effect element comprising the hard bias layer according to claim 16.

20. A magnetoresistive effect element comprising the hard bias layer according to claim 17.
